(19) United States
(12) Patent Application Publication
(10) Pub. No.: US 2022/0097140 A1
(43) Pub. Date: Mar. 31, 2022

(54) ADDITIVE MANUFACTURING BY LASER POWER MODULATION

(71) Applicants: AddUp, Cebazat (FR); Centre National De La Recherche Scientifique (CNRS), Paris (FR); Ecole Normale Superieure Paris-Saclay, Gif-sur-Yvette (FR)

(72) Inventors: GILLES WALRAND, CEBAZAT (FR); CHRISTOPHE TOURNIER, ANTONY (FR); SYLVAIN LAVERNHE, SACLAY VAL D'ALBIAN (FR); KAMEL ETTAIEB, CACHAN (FR)

(21) Appl. No.: 17/426,220

(22) PCT Filed: Jan. 28, 2020
(86) PCT No.: PCT/FR2020/050131

§ 371 Date: Jul. 28, 2021

(30) Foreign Application Priority Data
Jan. 28, 2019 (FR) 1900754

(51) Int. Cl. B22F 10/28; B33Y 10/00; B22F 12/00; B33Y 30/00; B33Y 50/02; B22F 10/36

(52) U.S. Cl. CPC B22F 10/28; B33Y 10/00; B22F 10/36; B33Y 30/00; B33Y 50/02; B22F 12/00

(57) ABSTRACT

A process for the selective additive manufacture of a three-dimensional object from a layer of powder comprises: applying a layer of additive manufacturing powder to a support or to a previously consolidated layer, emitting a laser beam onto a first point of the layer of additive manufacturing powder so as to consolidate a first zone of the layer of powder comprising the first point, adjusting a power of the laser beam depending on an estimated temperature variation of the layer of powder at a second point, separate from the first point, and emitting a laser beam onto the second point with the adjusted power so as to consolidate a second zone of the layer of powder comprising the second point, the emission of the laser beam onto the first point and onto the second point being temporally separated by the predetermined time interval.

### GENERAL TECHNICAL FIELD AND PRIOR ART

The present invention relates to the general field of selective additive manufacturing.

Selective additive manufacturing consists in creating three-dimensional objects by consolidating selected zones in successive layers of pulverulent material (metal powder, ceramic powder, etc.). The consolidated zones correspond to successive cross sections of the three-dimensional object. Consolidation takes place for example layer by layer, through total or partial selective melting carried out using a power source.

Conventionally, high-power laser sources or electron beam sources are used as the source for fusing the layers of powder.

Conventionally, during the process for manufacturing a three-dimensional object using a high-power laser source, the maximum temperature achieved by the powder may exceed the evaporation temperature, and the temperature field within a layer of powder exhibits significant gradients.

The loss of material by evaporation and the steep gradients bring about residual stresses which have an effect on the mechanical characteristics of the object, in particular local deformations, cracks on the micrometre scale or larger, causing micro-cracks and dislocations of layers.

There is therefore a need to control the temperature field of the layer of powder better during the manufacturing process.

### GENERAL SUMMARY OF THE INVENTION

An overall aim of the invention is to overcome the drawbacks of the prior art additive manufacturing processes.

In particular, an aim of the invention is to propose a solution for controlling the temperature field better during the process.

The aim is achieved in the context of the present invention by virtue of a process for the selective additive manufacture of a three-dimensional object from a layer of powder, the process comprising the steps of:
applying a layer of additive manufacturing powder to a support or to a previously consolidated layer,
emitting a laser beam onto a first point of the layer of additive manufacturing powder so as to consolidate a first zone of the layer of powder comprising the first point,
the process also comprising
adjusting a power of the laser beam depending on an estimated temperature variation of the layer of powder at a second point, separate from the first point, of the layer of powder that is caused by the emission of the laser beam so as to consolidate the first zone of the layer of powder, the estimated temperature variation depending on the distance between the first point and the second point and on a predetermined time interval,
emitting a laser beam onto the second point with the adjusted power so as to consolidate a second zone of the layer of powder comprising the second point, the emission of the laser beam onto the first point and the emission of the laser beam onto the second point being temporally separated by the predetermined time interval.

Such a process is advantageously supplemented by the following various features or steps considered on their own or in combination:
the estimated temperature variation ΔT is estimated in advance, depending on the distance r₂₁ between the first point and the second point and on the predetermined time interval (t₂-t₁), by calculating:

$$Δ T ( {r}_{21} , {t}_{2} - {t}_{1} ) = \frac{2 {Q}_{1}}{ɛ \sqrt{{π}^{3} ( {t}_{0} + ( {t}_{2} - {t}_{1} ) )}} \frac{1}{{R}^{2} + 8 a ( {t}_{0} + ( {t}_{2} - {t}_{1} ) )} exp ( \frac{- 2 {( {r}_{21} )}^{2}}{{R}^{2} + 8 a ( {t}_{0} + ( {t}_{2} - {t}_{1} ) )} )$$

Q₁ being an energy received by the layer during the emission of the laser beam so as to consolidate the first zone of the layer of powder, e being a thermal effusivity of the layer of powder, R being a radius of the laser beam, a being a thermal diffusivity of the layer of powder, and to being a predetermined moment.
A combination of the following two steps:
   a step of adjusting a power of the laser beam depending on an estimate of a temperature of the powder before consolidation Tp(tₙ) at a moment tₙ at an nth point of the layer, n being an integer greater than or equal to two, the estimate depending on the temperature variations of the powder that are caused by the emission of a laser beam so as to consolidate n-1 zones of the layer of powder,
   the nth point being located at the distance rₙ, from an ith point of the layer of powder, where

i=1,2, . . . (n−1)
each ith point being located within an ith zone of the consolidated layer of powder and being illuminated by the laser beam at the moment tᵢ, as follows:

$$Tp ( {t}_{n} ) = {T}_{0} + {\sum }_{i = 1}^{n - 1} Δ T ( {r}_{n i} , {t}_{n} - {t}_{i} )$$

in which To is the initial temperature of the powder, and
a step of emitting, at the moment tₙ, a laser beam towards the nth point so as to consolidate an nth zone of the layer of powder comprising the nth point, with the adjusted power.
in the estimate of a temperature of the powder before consolidation Tp(tₙ) at a moment tₙ at an nth point of the layer, each ith point of the (n-1) first points of the layer is located at a distance rₙᵢ from the nth point of the layer of powder such that

rₙᵢ≤Vl

in which Vl is a predetermined spatial neighbourhood, and each ith point corresponds to a moment tᵢ of emission of the laser beam towards the ith point such that

|tₙ−tᵢ|≤Vt

in which Vt is a predetermined temporal neighbourhood, where

i=1,2, . . . (n−1)

and n is an integer greater than or equal to two.
a power Pₙ of the laser beam emitted onto the nth point of the layer of additive manufacturing powder depending on an estimate of a temperature before consolidation Tp(tₙ) is calculated as follows

$${P}_{n} = \frac{1}{2 Δ t} ( T s - Tp ( {t}_{n} ) ) ( {R}^{2} + 8 a {t}_{0} ) ɛ \sqrt{{π}^{3} {t}_{0}}$$

in which Δt is a predetermined time increment and Ts is a predetermined threshold temperature.
a threshold temperature Ts is predetermined depending on at least one temperature objective chosen from the following conditions:
   a temperature of the powder that is to be achieved at a point over which the centre of the laser spot passes and at the time of the laser pass,
   a maximum temperature of the powder that is achieved over time at a point over which the centre of the laser spot passes,
   a maximum temperature of the powder that is achieved over time at a point of the layer of powder,
   an upper temperature that is not to be exceeded over time at any point of the layer of powder,
   a lower temperature that is not to be dropped below at any point of the powder, or
   a combination of these conditions that is optionally variable during the manufacturing process.
the laser scans along a discontinuous path comprising a first group of mutually parallel straight-line portions.
the laser scans along a continuous path comprising the first group of mutually parallel straight-line portions and a second group of straight-line portions, each straight-line portion of the second group joining a first end of a first straight-line portion of the first group and a second end of a second straight-line portion of the first group, the second straight-line portion being adjacent to the first straight-line portion.
the estimate of the temperature variation of the layer of powder at the nth point that is caused by the emission of the laser beam so as to consolidate one or more zones of the layer of powder is carried out once the manufacturing process has started.

The invention also relates to a selective additive manufacturing apparatus designed to implement the processes as described in this section.

In particular, the invention relates to an apparatus for the selective additive manufacture of a three-dimensional object from a layer of powder, the apparatus comprising:
a laser-type source,
a control unit configured to control the laser-type source such that the source emits a laser beam onto a first point of the layer of additive manufacturing powder, so as to consolidate a first zone of the layer of powder comprising the first point,

the apparatus also comprising:
a memory for storing an estimated temperature variation of the layer of powder at a second point of the layer of powder that is caused by the emission of the laser beam so as to consolidate the first zone of the layer of powder, the estimated temperature variation depending on the distance between the first point and the second point and on a predetermined time interval,

and wherein the control unit is configured to:
adjust a power of the laser beam depending on the estimated temperature variation stored in the memory,
control the laser-type source such that the source emits a laser beam onto the second point with the adjusted power so as to consolidate a second zone of the layer of powder comprising the second point, the emission of the laser beam onto the first point and the emission of the laser beam onto the second point being temporally separated by the predetermined time interval.

Advantageously, but optionally, the apparatus may be supplemented by a calculator or a simulator (C) designed to determine estimates of temperature variations of the layer of powder at an nth point that are caused by the emission of the laser beam so as to consolidate one or more zones of the layer of powder once the manufacturing process has begun.

### PRESENTATION OF THE FIGURES

Further features and advantages of the invention will become more apparent from the following description, which is purely illustrative and non-limiting and should be read in conjunction with the appended drawings, in which:

FIG. 1 is a schematic depiction of an additive manufacturing apparatus according to one possible embodiment of the invention.

FIG. 2 schematically shows a path which is located at the surface of a layer of powder and is scanned by a laser beam;

FIG. 3 schematically shows a field of the maximum temperature achieved by the powder when the layer of powder is scanned by a laser beam according to a technique known from the prior art;

FIG. 4 schematically shows changes, during scanning of a layer of powder by a laser beam according to a technique known from the prior art, in a power of the laser beam emitted towards the layer of powder, in a temperature of the powder before consolidation, in a temperature of the powder at the central point of the laser spot, and in a maximum temperature achieved by the powder;

FIG. 5 schematically shows a map of the temperature achieved by the powder at the central point of the laser spot, according to a technique known from the prior art;

FIG. 6 schematically shows changes, during scanning of a layer of powder by a laser beam according to one possible embodiment of the invention, in a power of the laser beam sent towards the layer of powder, in a temperature of the powder before consolidation, in a temperature of the powder at the central point of the laser spot, in a temperature objective of the powder at the central point of the laser spot, and in a maximum temperature achieved by the powder;

FIG. 7 schematically shows a field of the power of the laser beam sent towards the powder when the layer of powder is scanned by a laser beam according to one possible embodiment of the invention;

FIGS. 8a and 8b schematically show a detail of a path at the surface of a layer of powder scanned by a laser beam according to two techniques known from the prior art;

FIG. 9 schematically shows a path at the surface of a layer of powder scanned by a laser beam;

FIG. 10 schematically shows changes, during scanning of a layer of powder by a laser beam according to one possible embodiment of the invention, in a power of the laser beam emitted towards the layer of powder, in a temperature of the powder before consolidation, in a temperature of the powder at the central point of the laser spot, in a temperature objective of the powder at the central point of the laser spot, and in a maximum temperature achieved by the powder;

FIG. 11 schematically shows a field of the power of the laser beam sent towards the powder when the layer of powder is scanned by a laser beam according to one possible embodiment of the invention;

FIG. 12 schematically shows a field of the maximum temperature achieved by the powder when the layer of powder is scanned by a laser beam according to one possible embodiment of the invention;

FIG. 13 schematically shows a process for determining a spatial neighbourhood and a temporal neighbourhood of a point of the layer of powder;

FIG. 14 schematically shows a spatial neighbourhood and a temporal neighbourhood of a point of the layer of powder.

### DESCRIPTION OF ONE OR MORE IMPLEMENTATIONS AND EMBODIMENTS

### Selective Additive Manufacturing Apparatus

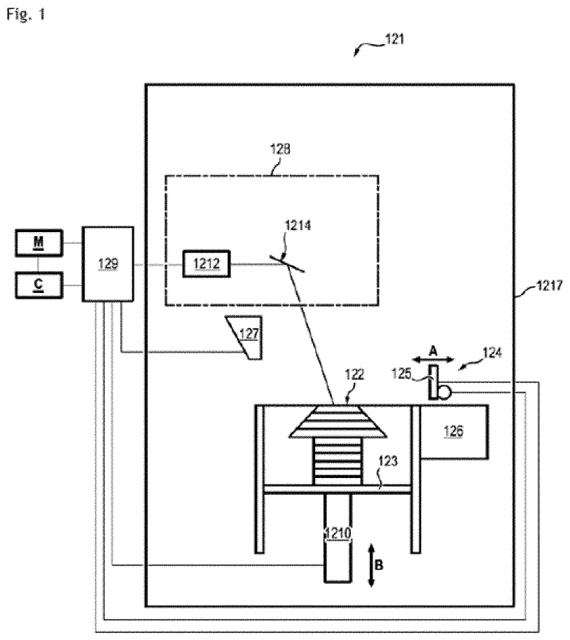

The selective additive manufacturing apparatus 1 in FIG. 1 comprises:
a support such as a horizontal plate 123 on which the various layers of additive manufacturing powder (metal powder, ceramic powder, etc.) are successively deposited, allowing a three-dimensional object to be manufactured (object 122 in the shape of a fir tree in FIG. 1),
a powder tank 127 located above the plate 123,
an arrangement 124 for the distribution of said metal powder over the plate, this arrangement 124 having for example a layering roller and/or spreader 125 for spreading the various successive layers of powder (movement along the double-headed arrow A),
an assembly 128 having at least one laser-type source 1212 for the (total or partial) melting of the spread fine layers, the laser beam generated by the source 1212 coming into contact with the spread fine layers in the powder plane, that is to say in the plane in which the layer of powder has been spread by the spreader 125,
a control unit 129 which controls the various components of the apparatus 121 depending on pre-stored information (memory M),
a mechanism 1210 for allowing the support for the plate 123 to be lowered as the layers are deposited (movement along the double-headed arrow B).

In the example described with reference to FIG. 1, at least one galvanometric mirror 1214 makes it possible to orient and move the laser beam from the source 1212 with respect to the object 122 depending on the information sent by the control unit 129. Any other deflection system may of course be envisaged.

The components of the apparatus 121 are arranged inside a sealed chamber 1217 which can be connected to an air or inert-gas processing circuit. The air or inert-gas processing circuit may also be designed to adjust the pressure within the sealed chamber 1217 to below or above atmospheric pressure.

Paths in the Layer of Powder that are Scanned by the Constant-Power Laser

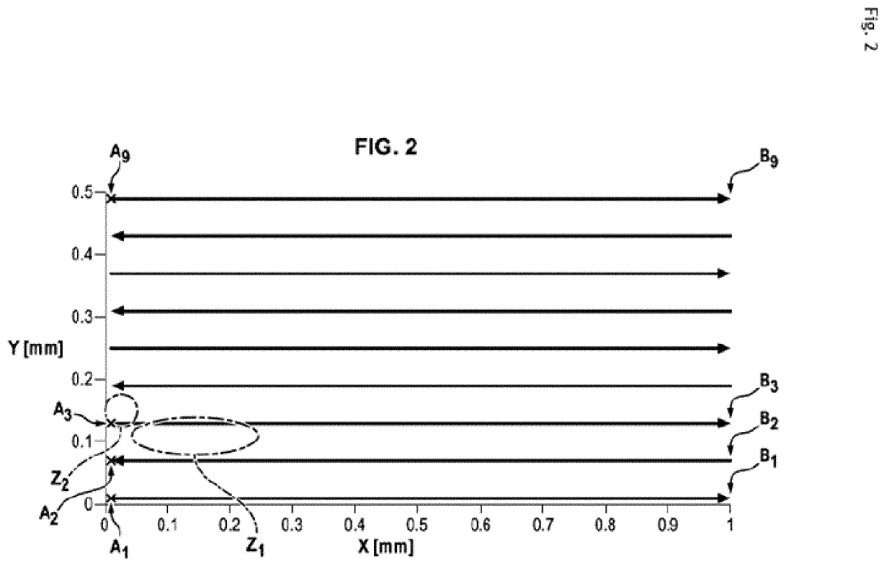

FIG. 2 schematically shows a path which is located at the surface of a layer of powder and is scanned by a laser beam.

According to a technique known from the prior art, the layer of powder is scanned by a laser beam in zigzags or back-and-forth movements so as to progressively consolidate the layer of powder.

The laser is emitted towards a first point A₁ of the layer of powder and scans over the layer of powder with a constant power and at a constant speed along a first straight-line portion oriented in the direction of an X axis as far as a point B₁. The first straight-line portion corresponds to a value of the Y coordinate close to 0 and is scanned in the positive direction of the X axis.

The length of the straight-line portion A₁ B₁ is equal to one millimetre in this example.

The scanning of the first straight-line portion by a laser beam makes it possible to locally supply enough energy to the layer of powder to melt the powder and consolidate a zone of the layer which comprises the first straight-line portion.

The emission of the laser towards the layer of powder is then interrupted.

The emission of the laser is reactivated such that the laser scans along a second straight-line portion with a constant power and at a constant speed from a point B₂ to a point A₂. This straight-line portion is parallel to the first straight-line portion. The second straight-line portion corresponds to a value of the Y coordinate greater than that of the previous straight-line portion and is scanned in the negative direction of the X axis.

The length of the second straight-line portion is the same as that of the first portion.

Again, the emission of the laser is interrupted and then reactivated to scan along a third straight-line portion with a constant power and at a constant speed in the positive direction of the X axis from a point A₃ to a point B₃. This straight-line portion is parallel to the two previous straight-line portions, corresponding to a value of the Y coordinate greater than that of the two previous straight-line portions.

Carrying on in this way, it is possible to scan along a ninth straight-line portion defined by the points A₉ and B₉ in FIG. 2, at a constant speed and with a constant power in the positive direction of the X axis.

The length of all the straight-line portions is one millimetre.

Thermal effects of the constant-power laser scan

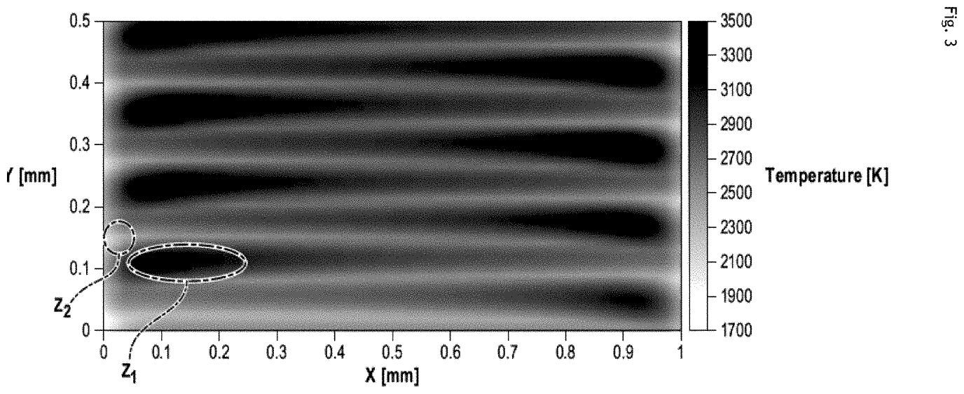

FIG. 3 schematically shows a field of the maximum temperature achieved by the powder as it is scanned by a laser beam along the path described in FIG. 2.

The temperature during the manufacturing process can be determined by numerical simulation at any point of the layer of powder.

For each point studied, it is possible to generate a temporal sequence of temperatures adopted by the powder at this point in the course of the process. It is possible to extract, from this temporal sequence, the maximum of its values, this maximum corresponding to the maximum temperature achieved by the powder at the studied point during the process.

The highest maximum temperatures are achieved at points of the layer of powder that are located towards one of the ends of the straight-line portions as defined above with regard to FIG. 2.

More specifically, of the two ends of the straight-line portion, it is the end that is scanned first by the laser.

The zone Z₁ shown in FIGS. 2 and 3 corresponds to such points of the layer of powder. They are located towards the end of the third straight-line portion that is scanned first by the laser.

The highest maximum temperatures correspond approximately to a temperature of 3500 Kelvin. This temperature may exceed the vaporization temperature of the additive manufacturing powder. This is the case in particular when the additive manufacturing powder is composed of Ti₆Al₄V, the vaporization temperature of which is 3473 K.

The vaporization of the powder may produce gaps in the manufactured object and projections onto zones that have already solidified, and this may deteriorate the quality, the surface state and the mechanical characteristics of the manufactured object.

Furthermore, the highest maximum temperatures are achieved at points of the layer of powder that are located relatively close to the points at which the maximum temperatures are lowest, around 1800 K.

The zone Z₂ shown in FIGS. 2 and 3 corresponds to points of the layer of powder at which the maximum temperatures are lowest. The zone Z₂ is located close to the zone Z₁.

Relatively steep temperature gradients are located between the zone Z₁ and the zone Z₂ of the layer of powder. More generally, the start of the scanning of a new straight-line portion is associated with relatively steep temperature gradients.

These gradients subsequently lead to the occurrence of residual stresses, which have an effect on the mechanical characteristics of the component and cause deformations and also cracks on the micrometre scale or larger.

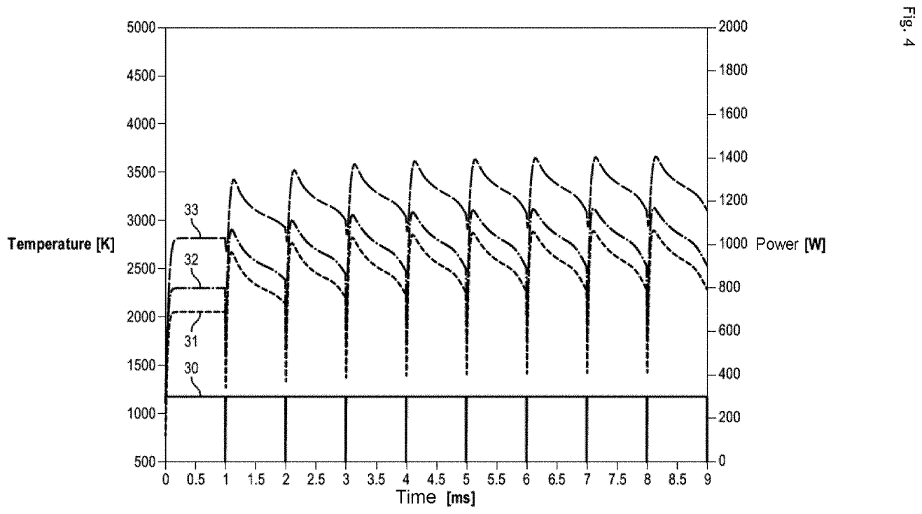

FIG. 4 schematically shows the changes in different quantities during the scanning of a layer of powder by a laser beam along a path shown in FIG. 2 and as described above, the different quantities being:
a power of the laser beam emitted towards the layer of powder 30,
a temperature of the powder before consolidation 31,
a temperature of the powder at the central point of the laser spot 32, and
a maximum temperature of the powder 33, in this instance the maximum temperature during the manufacturing process that is achieved by the powder at a point scanned by the centre of the laser spot.

The curve of the power 30 of the laser beam represented as a function of time reveals the scan times of each straight-line portion as described above in the description of FIG. 2.

The speed at which the laser beam scans over the layer of powder is one metre per second.

Since the length of each straight-line portion is one millimetre, the laser beam scans along each straight-line portion in one millisecond.

Between two straight-line portions, the emission of the laser beam is suspended and the power drops to zero.

The curve of the power 30 of the laser beam over time corresponds to a series of square waves with a width of one millisecond and a constant height. Each straight-line portion is scanned by the laser with a constant power of 300 W.

Each straight-line portion corresponds to a square wave, and each moment u indicated on the horizontal Time axis corresponds to a point M of the layer of powder that is located on the path towards which the laser is emitted at the moment u. The centre of the laser spot scans over the point M at the moment u.

The laser spot is understood to correspond to a cross section of the laser beam that is located at the intersection between the laser beam and the layer of powder.

The laser spot may have a circular shape.

The temperature of the powder before consolidation 31 is an estimate of the temperature Tp of the layer of powder at the point M, just after the moment u. This estimate characterizes the diffusion at the point M of the energy supplied by the laser beam to the layer of powder before the moment u. The curve 31 is obtained by numerical simulation.

The temperature of the powder at the central point of the laser spot 32 is the temperature of the powder at a point scanned by the centre of the laser spot at the time of the laser pass. It corresponds to the estimate of the temperature of the powder at the point M just after the moment u. The curve 32 is obtained by numerical simulation.

The maximum temperature achieved by the powder 33 is an estimate of the maximum temperature that is achieved by the powder at a point M during the manufacturing process. This estimate takes into account the energy supplied by the laser towards the point M at the moment u and also the diffusion to the point M of the energy supplied to the layer of powder by the laser before the moment u.

The curve 33 has peaks just after the start of each square wave of the curve 30. The temperatures corresponding to these peaks exceed 3500 K and possibly the vaporization temperature of the additive manufacturing powder.

The curves 31, 32 and 33 exhibit certain similar variations. In particular, the curves 31, 32 and 33 exhibit an abrupt signal drop around each square-wave end of the curve 30, and this signal drop is followed by an abrupt increase and then a slower decrease during the next square wave of the curve 30 before exhibiting a new abrupt signal drop around the end of this next square wave.

The scanning of a straight-line portion of the layer of powder corresponds to a maximum achieved temperature that is low at the start of the scan, then abruptly much higher before decreasing gradually up to the end of the scanning of the straight-line portion. The temperature before consolidation Tp and the temperature achieved by the powder at the central point of the laser spot follow the same changes.

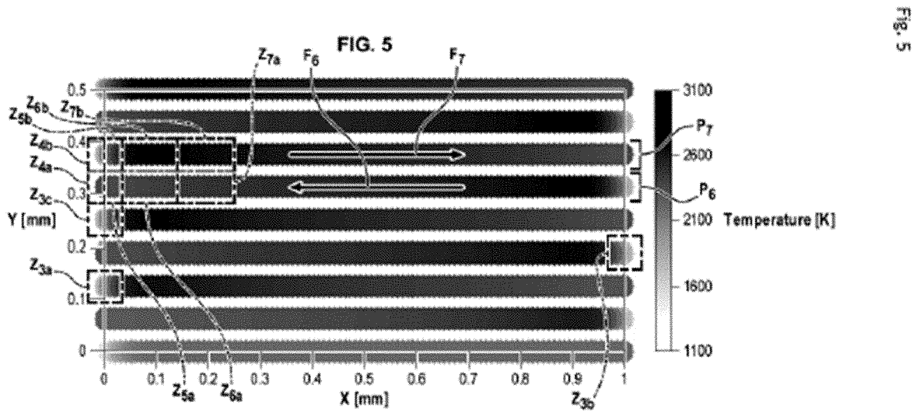

FIG. 5 schematically shows a map of the temperature achieved by the powder at the central point of the laser spot, when the layer of powder is scanned by a laser beam along the path in FIG. 2, as was described above.

FIG. 5 and the curve 32 in FIG. 4 provide two depictions of the same quantity: “temperature achieved by the powder at the central point of the laser spot”. In FIG. 5, this depiction is spatial, whereas for the curve 32 in FIG. 4, this depiction is temporal.

The temperature at the central point of the laser spot is low at the start of the scanning of a straight-line portion, and then abruptly much higher. The zones Z₃a, Z₃b and Z₃c identified in FIG. 5 correspond to this variation.

Once this abrupt increase has passed, the temperature at the central point of the laser spot decreases more gently up to the end of the scanning of the straight-line portion.

These variations in temperature at the central point of the laser spot result from different effects.

For the one part, when the laser scans along a straight-line portion, a part of the energy supplied by the laser diffuses towards the next straight-line portion in the scanning order of the laser.

The next straight-line portion is heated, in particular in the zone adjacent to the points that have just been scanned by the laser. Over time, the energy diffuses further into the powder, such that the energy coming from the scanned straight-line portion which has diffused to the points in the adjacent zone of the next straight-line portion passes through a maximum before decreasing.

For the other part, the emission of the laser beam towards the layer of powder is interrupted at the end of the scanning of the straight-line portion, and then reactivated at the start of the next straight-line portion. This discontinuity causes a decrease in the supply of energy from one straight-line portion to the next straight-line portion.

For these reasons, the temperature of the powder before consolidation 31 is lower at the very start of the straight-line portion than in the rest of the straight-line portion. This difference in temperature before consolidation can be seen from the curve 31 in FIG. 4 and corresponds to the drop in the signal in this curve that is located around each square-wave end of the curve 30.

The temperature of the central point of the laser spot depends in particular on the temperature before consolidation at the scanned point, i.e. the energy coming from the previous straight-line portion which is present at this point at the time it is scanned by the laser.

The sixth and seventh portions P6 and P7 are indicated in FIG. 5. They are scanned in the direction of the arrows F6 and F7. Different zones have been identified in these portions; they are scanned by the laser in the following order: Z₇ₐ, Z₆ₐ, Z₅ₐ, Z₄a, Z_{4b}, Z_{5b}, Z_{6b} and Z_{7b}.

Relatively less energy is diffused from the previously scanned zones at the very start of the straight-line portion, for example in the zone Z_{4b}, on account of the interruption of the laser emission between the zones Z₄a and Z_{4b}.

Relatively more energy is diffused from the previously scanned zones immediately after the very start of the straight-line portion, for example in the zone Z_{5b}, since the part of the previous straight-line portion that is located adjacent thereto, the zone Z₅ₐ, has recently been scanned by the laser.

Relatively less and less energy is diffused from the previously scanned zones into the rest of the straight-line portion, since the part of the previous straight-line portion that is located adjacent thereto was scanned by the laser an increasingly long time ago.

The energy received in the zone Z₆ₐ, which diffused into the zone Z_{6b} at the time the zone Z_{6b} was scanned, is:
less than the energy received in the zone Z₅ₐ, which diffused into the zone Z_{5b} at the time the zone Z_{5b} was scanned, and
more than the energy received in the zone Z₇ₐ, which diffused into the zone Z_{7b} at the time the zone Z_{7b} was scanned.

The temperature field illustrated in FIG. 5 corresponds to the temperature field at the central point of the laser spot. This field is non-uniform with steep temperature gradients, in particular at the ends of the straight-line portions that are scanned first.

Paths in the Layer of Powder that are Scanned by the Modulated-Power Laser

A method is proposed for better controlling the temperature field achieved by the powder at the centre of the laser spot, and consequently the field of the maximum temperature that is achieved, by modulating the power of the laser as it scans the powder.

A path in the layer of powder to be scanned at a constant speed by the laser is chosen. This path can be split up virtually into segments Sn for example of identical length, which then correspond to identical laser scan durations. Each segment Sn can be characterized in particular by an nth point of the layer of powder contained in the segment Sn and a moment tₙ from which the segment is scanned by the laser.

The power of the laser beam with which each segment is scanned is calculated in the order in which the different segments are scanned.

For the nth segment Sn, this calculation comprises the following steps:
calculating an estimate of the temperature of the powder before consolidation Tp(tₙ), at the nth point of the layer of powder contained in the segment Sn and at the moment tₙ, the estimate depending on the temperature variations of the powder that are caused, at the nth point of the layer of powder and at the moment tₙ, by the emission of a laser beam so as to scan over the n−1 segments located upstream on the path, each of the n−1 segments being scanned with a previously calculated power,
calculating a temperature variation objective to be accomplished that is equal to the temperature difference between a threshold temperature Ts and the temperature of the powder before consolidation Tp(tₙ), the threshold temperature Ts being a temperature of the layer that is to be achieved without being exceeded at the central point of the laser spot, and
calculating a power of the laser beam emitted so as to scan over the nth segment Sn depending on the temperature variation objective.

The modulation of the laser power is calculated for all of the segments in the order in which they are scanned.

Thermal Effects of the Modulated-Power Laser Scan

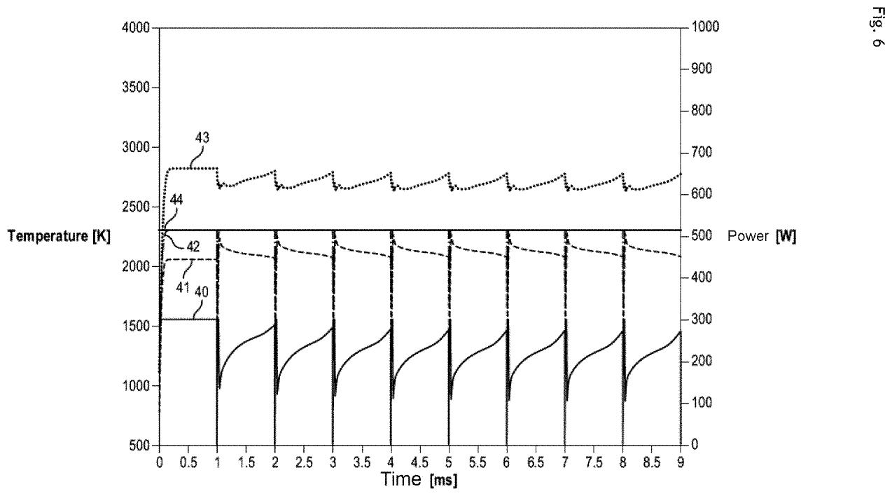

FIG. 6 corresponds to the application of such a method in the case of the scanning of a layer of powder by a laser beam along the path shown in FIG. 2. FIG. 6 schematically shows the changes in different quantities during the scan, the different quantities being:
a power of the laser beam emitted towards the layer of powder 40,
a temperature of the powder before consolidation 41,
a temperature of the powder at the central point of the laser spot 42,
a maximum temperature of the powder 43, in this instance the maximum temperature during the manufacturing process that is achieved by the powder at a point scanned by the centre of the laser spot, and
a temperature objective of the powder 44 at the central point of the laser spot.

The curves 41, 42 and 43 are obtained by numerical simulation.

The quantities represented in the curves 41, 42 and 43 are defined respectively in the same way as the quantities represented in the curves 31, 32 and 33, but in the case in which the method for better controlling the temperature field is applied.

The speed at which the laser beam scans over the layer of powder is one metre per second.

Since the length of each straight-line portion is one millimetre, the laser beam scans along each straight-line portion in one millisecond.

Between two straight-line portions, the emission of the laser beam is suspended and the power drops to zero.

The curve of the power 40 of the laser beam over time exhibits signal drops to zero at one millisecond, two milliseconds, and so on at every millisecond. The scanning of each straight-line portion corresponds to a time interval between two signal drops to zero.

The curve of the power 40 of the laser beam during the first millisecond is constant, the power being kept constant while the first straight-line portion is being scanned.

For scanning along the following straight-line portions, the power of the laser beam is at a maximum at the very start of the straight-line portion, then decreases abruptly before increasing more gently during scanning.

These variations in the power of the laser beam during scanning are opposite to the variations in the maximum temperature as described in the case of the maximum temperature curve 33 in FIG. 4.

The curve of the temperature of the powder before consolidation 41 in FIG. 6 exhibits certain variations similar to the curve of the temperature of the powder before consolidation 31 in FIG. 4.

In particular, the curve 41 exhibits an abrupt signal drop around each end of scanning along a straight-line portion, and this drop in signal is followed by an abrupt increase and then a slower decrease while scanning along the next straight-line portion.

The amplitude of the variations in the curve 41 is, however, smaller than the amplitude of the variations in the curve 31: starting from the second straight-line portion scanned by the laser beam, the curve 41 changes between the temperature values of 1200 K and 2200 K, i.e. a range of 1000 K, while the curve 31 changes between the temperature values of 1400 K and 2700 K, i.e. a range of 1300 K.

The effect of the scanning of the segments by the laser on the temperature of a segment located downstream on the path is lower compared with the situation in FIGS. 4 and 5.

The curve 44 represents a temperature objective of the powder at the central point of the laser spot. More specifically, this is a temperature of the powder that is to be achieved without being exceeded at a point of the layer of powder scanned by the centre of the laser spot at the time of the laser pass.

The curve 44 is constant: the temperature of the layer that is to be achieved without being exceeded at the central point of the laser spot is the same during the laser scan and during the manufacturing process. This temperature may be referred to as the threshold temperature Ts.

At the very start of the scanning of each straight-line portion, the curve 42 is lower than the curve 44, and then, during the rest of the scanning of the straight-line portion, the two curves 42 and 44 coincide. The temperature objective of the powder at the central point of the laser spot is achieved rapidly after the start of the scanning of each straight-line portion by the laser beam.

The amplitude of the variations in the curve 42 is smaller than the amplitude of the variations in the curve 32: starting from the second straight-line portion scanned by the laser beam, the curve 42 changes between the temperature values of 1800 K and 2300 K, i.e. a range of 500 K, while the curve 32 changes between the temperature values of 1600 K and 3100 K, i.e. a range of 1500 K. The method makes it possible to drastically reduce the variations in the temperature of the powder at the central point of the laser spot compared with the situation in FIG. 4.

The curve 43 has peaks shortly after the start of scanning of each straight-line portion by the laser beam. The temperatures corresponding to these peaks do not exceed 3000 K and are far below the vaporization temperature of the material Ti6Al4V.

The temperature achieved by the powder during the application of the novel method can thus be lower than the vaporization temperature of the powder. This makes it possible to reduce the energy consumed during the additive manufacturing process and to avoid vaporizations and gaps of material in the manufactured object.

The amplitude of the variations in the curve 43 is much smaller than the amplitude of the variations in the curve 33: starting from the second straight-line portion scanned by the laser beam, the curve 43 changes between the temperature values of 2600 K and 2900 K, i.e. a range of 300 K, while the curve 33 changes between the temperature values of 2900 K and 3600 K, i.e. a range of 700 K.

The method makes it possible to reduce the variations in the maximum achieved by the powder at the central point of the laser spot compared with the situation in FIG. 4.

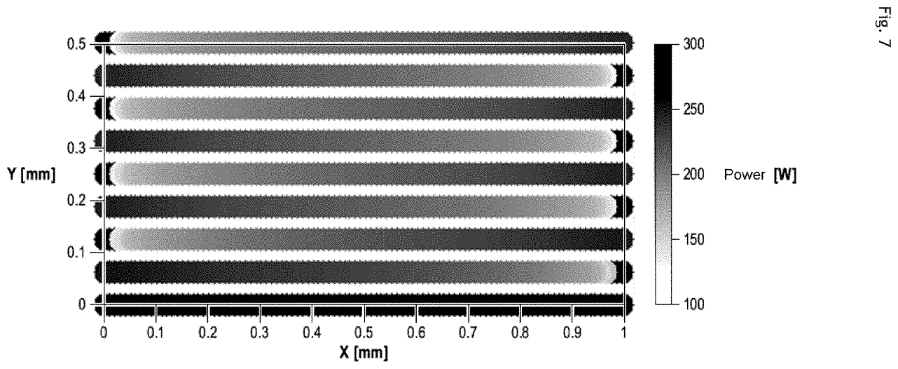

FIG. 7 schematically shows a field of the power of the laser beam sent towards the powder, in the same mode of scanning the layer of powder by a laser beam as the one in FIG. 6.

As already represented on the curve 40 in FIG. 6, the power is constant, equal to around 300 W, during the first straight-line portion located at the bottom of FIG. 7.

For each following straight-line portion, the power of the laser beam is at a maximum at the start of scanning, then drops abruptly before increasing again more gently during scanning.

Scanning Paths with Discontinuities

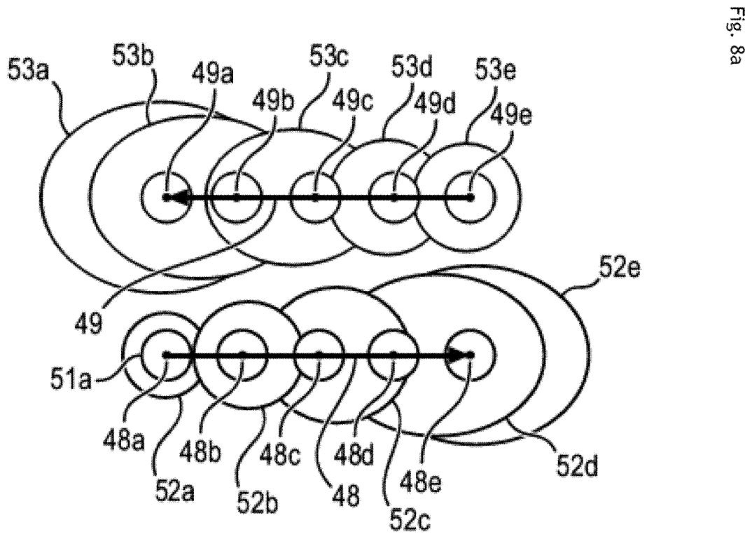

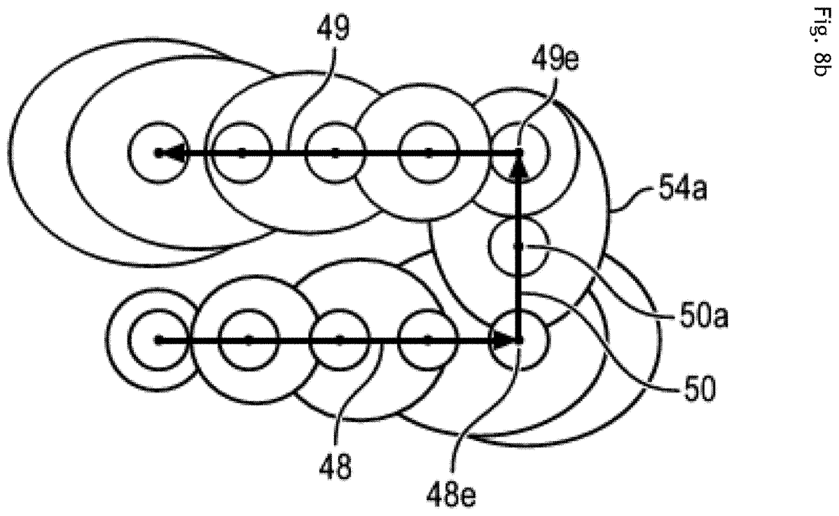

FIG. 8a schematically shows a detail of a path along which a layer of powder is scanned by a laser beam along a path shown in FIG. 2 and as described above. The power of the laser beam is modulated during scanning according to the proposed method in order to better control the temperature field.

The path has a discontinuity between the straight-line portion 48 and the next straight-line portion 49.

The laser scans along the straight-line portion 48 and passes in particular over the points 48a, 48b, 48c, 48d and 48e. These points correspond to the ends of the segments Sn of identical length which virtually split up the straight-line portions scanned by the laser and for which a power of the laser beam is calculated.

The circle 51a corresponds to the laser spot that illuminates the layer of powder at the point 48a. The area 52a corresponds to the thermal effect of the laser scan as far as the point 48a. The area 52a is larger, the higher the temperature that is achieved at the point 48a. The area 52a depends both on the power of the laser beam sent to the point 48a and on the energy that is supplied by the laser to the layer of powder upstream of the point 48a and has diffused as far as the point 48a.

The thermal effects of the laser scan increase during the scanning of the straight-line portion 48. The areas 52b, 52c, 52d and 52e are increasingly large. The power of the laser beam increases during scanning, as mentioned in the description of FIG. 7. The energy diffused in the layer of powder in the scanning direction is increasingly large during the scanning of the straight-line portion 48. At the point 48e, the emission of the laser is interrupted. It is reactivated such that the laser beam is emitted towards the point 49e. The laser beam then scans the straight-line portion 49 in the opposite direction to the straight-line portion 48, from the point 49e to the point 49a, The thermal effects of the laser scan increase during the scanning of the straight-line portion 49. The areas 53e, 53d, 53c, 53b and 53a are, in that order, increasingly large.

The area 53e corresponding to the thermal effect of the laser scan as far as the point 49e is substantially smaller than the area 52e. The discontinuity of the scan, that is to say the interruption of the emission of the laser between the points 48e and 49e, and the change in the scanning direction between these points help to decrease the energy diffused in the layer of powder between the points 48e and 49e.

Even with a much higher power of the laser beam emitted towards the point 49e than the power of the laser beam emitted towards the point 48e, as mentioned in the description of FIG. 7, the thermal effect of the laser scan is much greater at the point 48e than at the point 49e.

The field of the temperature achieved by the powder at the centre of the laser spot achieved is not uniform along the path scanned in the case of FIG. 8a and FIG. 6. In particular, at the very start of scanning of a straight-line portion by the laser beam, the temperature curve of the powder before consolidation 41 and the temperature curve of the powder at the central point of the laser spot 42 both exhibit a signal drop.

Scanning Paths without Discontinuities

A form of path is proposed in order to limit the drop in temperature of the powder before consolidation and the drop in temperature of the powder at the central point of the laser spot at the very start of scanning of a straight-line portion.

FIG. 8b schematically shows a detail of a form of path proposed to this end. The power of the laser beam is modulated during scanning according to the proposed method in order to better control the temperature field.

The path exhibits a continuity between the straight-line portion 48 and the next straight-line portion 49, with the addition of a straight-line portion 50 which joins the end 48e of the straight-line portion 48 and the end 49e of the straight-line portion 49e. The straight-line portion 50 is scanned by the laser beam from the point 48e to the point 49e by passing notably over the point 50a, with which the area 54a that characterizes the thermal effect of the laser scan as far as the point 50a is associated.

Compared with the path illustrated in FIG. 8a, the path in FIG. 8b is continuous and corresponds to smaller changes in the scanning direction.

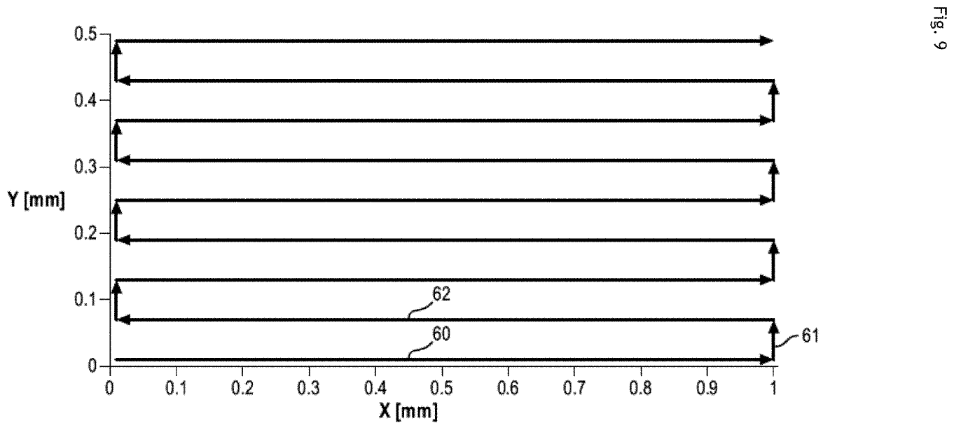

FIG. 9 schematically shows a path at the surface of a layer of powder scanned by a laser beam with a proposed path form.

The path is continuous and comprises a first group of parallel straight-line portions that correspond to the parallel straight-line portions of the path shown in FIG. 2. The path in FIG. 9 comprises a second group of straight-line portions, each straight-line portion of the second group joining a first end of a first straight-line portion of the first group and a second end of a second straight-line portion of the first group, the second straight-line portion being adjacent to the first straight-line portion.

Each passage from a straight-line portion of the first group of straight-line portions to the next one in this first group, for example the passage from the straight-line portion 60 to the straight-line portion 62, is made continuous by the addition of a straight-line portion of the second group of straight-line portions, for example the straight-line portion 61.

Thermal Effects of the Modulated-Power Laser Scan in the Case of Scanning Paths without Discontinuities

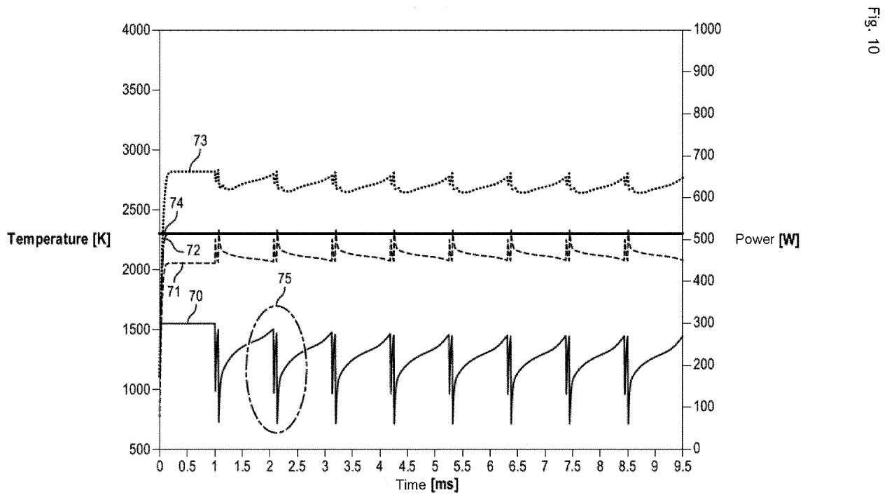

FIG. 10 corresponds to the application of the method proposed for better controlling the temperature field to the scanning of a layer of powder by a laser beam along the path illustrated in FIG. 9.

FIG. 10 schematically shows the changes in different quantities during the scan, the different quantities being:
a power of the laser beam emitted towards the layer of powder 70,
a temperature of the powder before consolidation 71,
a temperature of the powder at the central point of the laser spot 72,
a maximum temperature of the powder 73, in this instance the maximum temperature during the manufacturing process that is achieved by the powder at a point scanned by the centre of the laser spot, and
a temperature objective of the powder 74 at the central point of the laser spot.

The curves 71, 72 and 73 are obtained by numerical simulation.

The quantities represented in the curves 71, 72 and 73 are defined respectively in the same way as the quantities represented in the curves 31, 32 and 33, but in the case in which the method for better controlling the temperature field is applied to the case of a continuous path.

Since the speed of scanning the layer of powder by the laser beam is one metre per second, and since the length of each straight-line portion of the first group of straight-line portions is one millimetre, the laser beam scans along each straight-line portion of the first group in one millisecond.

The curve of the power 70 of the laser beam during the first millisecond is constant, the power being kept constant while the first straight-line portion is being scanned.

Between two straight-line portions of the first group, the power of the laser beam does not drop to zero, and a certain time is necessary for the laser to scan along the straight-line portion of the second group.

The curve of the power 70 exhibits, starting from the second straight-line portion of the first group, a regular pattern and a time period that is greater than one millisecond.

In this pattern, the power of the laser beam decreases and then increases rapidly twice before increasing more gently during the scan. The contour 75 surrounds a zone of the curve 70 that has the two consecutive sequences of decrease and rapid increases of the signal.

Each of the two consecutive sequences corresponds to a change in the scanning direction of the laser.

The first sequence corresponds to the transition from a straight-line portion of the first group to a straight-line portion of the second group.

The second sequence corresponds to the transition from the straight-line portion of the second group to a straight-line portion of the first group.

At each straight-line portion transition, and as in the case of the curve of the power 40 in FIG. 6, the power of the laser beam passes through a maximum at the very start of the straight-line portion, then decreases abruptly.

The curve of the temperature of the powder before consolidation 71 exhibits variations, which, starting from the second straight-line portion of the first group, are regular with the same time period of greater than one millisecond as the time period described for the curve 70.

These variations have a much smaller amplitude than the variations of the curve 41 in FIG. 6. In particular, the signal drop of the curve 41 followed by an abrupt increase corresponding to a start of a straight-line portion of the first group does not appear in the curve 71. Starting from the second straight-line portion scanned by the laser, the curve 71 changes between the temperature values of 2000 K and 2300 K, i.e. a range of 300 K, while the curve 41 changes between the temperature values of 1200 K and 2200 K, i.e. a range of 1000 K.

The temperature of the powder before consolidation at the very start of a straight-line portion of the first group has been increased in FIG. 10 compared with the situation in FIG. 6.

Like the curve 44 in FIG. 6, the curve 74 is constant: the temperature of the layer that is to be achieved without being exceeded at the central point of the laser spot is the same during the laser scan and during the manufacturing process. This temperature may be referred to as the threshold temperature Ts.

At the very start of the scanning of the path, the curve 72 is lower than the curve 44, and then, during the rest of the scanning of the path, the two curves 42 and 44 coincide. The temperature objective of the powder at the central point of the laser spot is achieved rapidly after the start of the scanning of the first straight-line portion by the laser beam.

The amplitude of the variations in the curve 72 is much smaller than the amplitude of the variations in the curve 42: starting from the second straight-line portion scanned by the laser beam, the curve 72 appears constant, while the curve 42 changes between the temperature values of 1600 K and 2300 K, i.e. a range of 700 K.

The continuous path proposed makes it possible to drastically reduce the variations in the temperature of the powder at the central point of the laser spot compared with the situation in FIG. 6.

Starting from the second straight-line portion of the first group, the curve 73 exhibits a regular pattern with the same time period of greater than one millisecond as the time period described for the curves 70 and 71.

The maximum temperatures achieved during these patterns do not exceed 3000 K and are far below the vaporization temperature of the material Ti6Al4V.

The temperature achieved by the powder during the application of the novel method and along the continuous path proposed can thus be lower than the vaporization temperature of the powder. This makes it possible to reduce the energy consumed during the additive manufacturing process and to avoid vaporizations and gaps of material in the manufactured object.

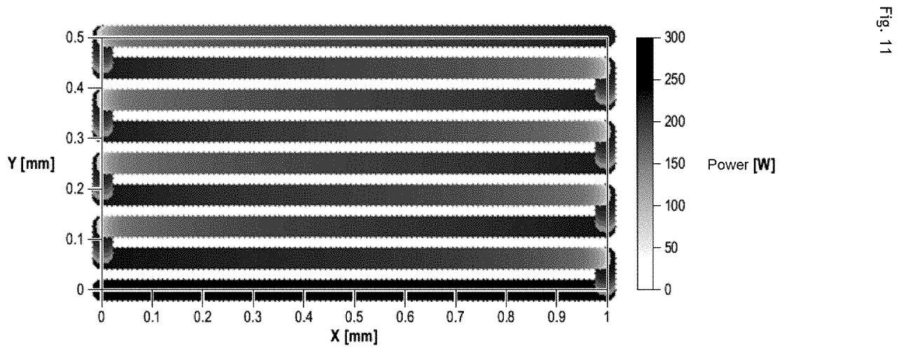

FIG. 11 schematically shows a field of the power of the laser beam sent towards the powder, in the same mode of scanning the layer of powder by a laser beam as the one in FIG. 10.

As already represented on the curve of the power 70 in FIG. 10, the power of the laser beam is constant, equal to around 300 W, during the first straight-line portion located at the bottom of FIG. 11.

For each following straight-line portion, of the first group and of the second group, the power of the laser beam is at a maximum at the very start of scanning, then drops abruptly before increasing again more gently during the scanning of the straight-line portion. The continuity of the path makes the very end of the scanning of a straight-line portion and the very start of the scanning of the next straight-line portion coincide.

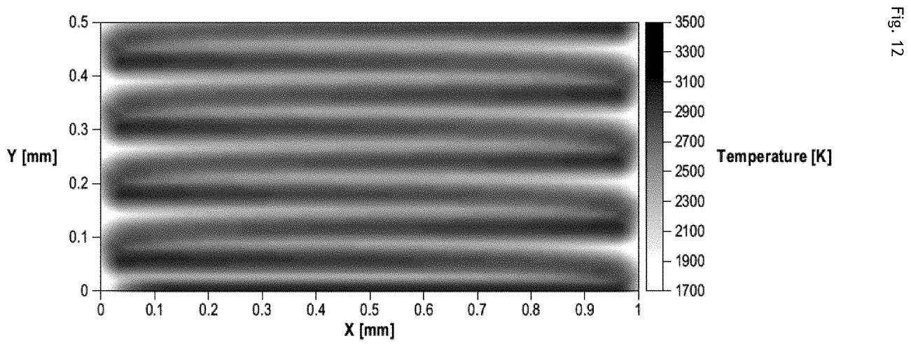

FIG. 12 schematically shows a field of the maximum temperature achieved by the powder, when the layer of powder is scanned by the laser beam, in the same mode of scanning the layer of powder by a laser beam as the one in FIG. 10.

The maximum-temperature field is more uniform in FIG. 12 than in FIG. 3. The maximum temperature is between 1700 K and 2800 K in FIG. 12, while it is between 1800 K and 3500 K in FIG. 3.

The temperature gradients in the case of FIG. 12 are less steep than in the case of FIG. 3.

Estimate of the Temperature of the Powder before Consolidation Tp—Case of Two Points

The temperature of the powder before consolidation, which is shown on the curves 31 in FIG. 4, 41 in FIG. 6, 71 in FIG. 10 in different powder consolidation strategy situations, is an estimate of the temperature Tp of the layer of powder at a point on the layer of powder just before the laser scans over this point.

This estimate takes into account the diffusion to said point of the energy previously supplied to the layer of powder by the laser.

For example, in the case of an emission of a laser beam onto a first point of the layer of additive manufacturing powder so as to consolidate a first zone of the layer of powder comprising a first point, a temperature variation of the layer of powder at a second point, separate from the first point, of the layer of powder that is caused by the emission of the laser beam so as to consolidate the first zone of the layer of powder can be estimated depending on the distance between the first point and the second point and on a predetermined time interval. More specifically, this estimated temperature variation ΔT can be determined as follows depending on the distance r₂₁ between the first point and the second point and on a predetermined time interval (t₂-t₁):

$$Δ T ( {r}_{21} , {t}_{2} - {t}_{1} ) = \frac{2 {Q}_{1}}{ɛ \sqrt{{π}^{3} ( {t}_{0} + ( {t}_{2} - {t}_{1} ) )}} \frac{1}{{R}^{2} + 8 a ( {t}_{0} + ( {t}_{2} - {t}_{1} ) )} exp ( \frac{- 2 {( {r}_{21} )}^{2}}{{R}^{2} + 8 a ( {t}_{0} + ( {t}_{2} - {t}_{1} ) )} )$$

in which: Q₁ is the energy received by the layer during the emission of the laser beam so as to scan over the first segment, ε is a thermal effusivity of the layer of powder, R is a radius of the laser beam, a is a thermal diffusivity of the layer of powder, and to is a predetermined moment.

t₀ is a parameter of the model, defining the lower limit of temporal validity. Its value can be determined depending on the time increment Δt, for example such that t₀=10×Δt, where Δt=10 microseconds.

The energy Q₁ can be defined as being the product of the power of the laser beam emitted onto the first point and the emission time of the laser beam onto this first point. If the laser beam is scanned along a path, it is possible to define a time increment Δt and to divide the path into portions, each portion being scanned by the laser beam for a time equal to the time increment Δt. If these portions are sufficiently small, it is possible for the energy sent towards the portion to be considered to be sent at a single point of the portion.

The case in which the laser spot has a circular shape defined by a radius R will be considered.

The formula used here originates from a model which applies to the diffusion of heat in solids, this model also being able to be applied to solid additive manufacturing powders including metal ceramic powders.

The formula

∴T(r₂₁, t₂−t₁)

can be interpreted as being the variation at the moment t₂ in the temperature of the layer of powder at the second point that is caused by the emission at the moment t₁ of the laser beam so as to consolidate the first zone of the layer of powder.

This formula can be used to establish the temperature of the powder at the second point at any moment after the moment t₁.

In particular, this formula can be used to establish the temperature of the powder before consolidation Tp(t₂) at the second point, that is to say the temperature of the powder at the second point just before the laser illuminates this second point.

The temperature of the powder before consolidation Tp(t₂) at the second point located at the distance r₂₁ from the first point of the layer of powder at the moment t₂ can be estimated from the relationship

Tp(t₂)=T₀+ΔT(r₂₁, t₂−t₁)

in which T₀ is the initial temperature of the powder.

The emission of a laser beam onto the first point of the layer of additive manufacturing powder takes place at the moment t₁.

This estimate makes it possible to implement a process for the selective additive manufacture of a three-dimensional object from a layer of powder, the process comprising the steps of:
applying a layer of additive manufacturing powder to a support or to a previously consolidated layer,
emitting a laser beam onto a first point of the layer of additive manufacturing powder so as to consolidate a first zone of the layer of powder comprising the first point,
the process being characterized in that it also comprises
adjusting a power of the laser beam depending on an estimated temperature variation of the layer of powder at a second point, separate from the first point, of the layer of powder that is caused by the emission of the laser beam so as to consolidate the first zone of the layer of powder, the estimated temperature variation depending on the distance between the first point and the second point and on a predetermined time interval,
emitting a laser beam onto the second point with the adjusted power so as to consolidate a second zone of the layer of powder comprising the second point, the emission of the laser beam onto the first point and the emission of the laser beam onto the second point being temporally separated by the predetermined time interval.

Said adjusted power, denoted P₂, can be calculated depending on the estimate of the temperature before consolidation Tp(t₂) as follows:

$${P}_{2} = \frac{1}{2 Δ t} ( Ts - Tp ( {t}_{2} ) ) ( {R}^{2} + 8 a {t}_{0} ) ɛ \sqrt{{π}^{3} {t}_{0}}$$

in which Δt is a time increment, Ts is a predetermined threshold temperature and t₀ is a predetermined moment.

In this particular situation, the following can be chosen

Δt=(t₂−t₁).

Estimate of the Temperature of the Powder Before Consolidation Tp—Case of n Points

More generally, the temperature before consolidation can be estimated in the situation of a path in the layer of powder comprising several points illuminated by the laser.

The temperature of the powder before consolidation Tp(tₙ) at a moment tₙ at an nth point, n being an integer greater than or equal to two, can be estimated knowing the energy supplied by the laser beam to the layer of powder before the moment tₙ.

Each ith point, where

i=1, 2, . . . (n−1)

is illuminated by the laser beam at the moment tᵢ and is located within an ith zone of the layer of powder consolidated by virtue of the energy Qᵢ supplied by the laser beam around the moment tᵢ.

The distance between the ith point and the nth point is denoted rₙᵢ.

The supply of the energy Qᵢ towards the layer of powder produces an estimated temperature variation

ΔT(rₙᵢ, tₙ−tᵢ)

at the moment tₙ at the nth point of the layer. This variation is calculated as follows:

$$Δ T ( {r}_{21} , {t}_{2} - {t}_{1} ) = \frac{2 {Q}_{1}}{ɛ \sqrt{{π}^{3} ( {t}_{0} + ( {t}_{2} - {t}_{1} ) )}} \frac{1}{{R}^{2} + 8 a ( {t}_{0} + ( {t}_{2} - {t}_{1} ) )} exp ( \frac{- 2 {( {r}_{21} )}^{2}}{{R}^{2} + 8 a ( {t}_{0} + ( {t}_{2} - {t}_{1} ) )} )$$

The sum of these variations allows an estimate of a temperature of the powder before consolidation Tp(tₙ) as follows:

$$Tp ( {t}_{n} ) = {T}_{0} + {\sum }_{i = 1}^{n - 1} Δ T ( {r}_{n i} , {t}_{n} - {t}_{i} )$$

in which T₀ is the initial temperature of the powder.

This estimate makes it possible to implement a process for the selective additive manufacture of a three-dimensional object from a layer of powder, the process comprising the steps of:
adjusting a power of the laser beam depending on an estimate of a temperature of the powder before consolidation Tp(tₙ) at a moment tₙ at an nth point of the layer, n being an integer greater than or equal to two, the estimate depending on the temperature variations of the powder that are caused by the emission of a laser beam so as to consolidate n−1 zones of the layer of powder,

the nth point being located at the distance rₙᵢ from an ith point of the layer of powder, where

i=1, 2, . . . (n−1)

each ith point being located within an ith zone of the consolidated layer of powder and being illuminated by the laser beam at the moment tᵢ, as follows:

$$Tp ( {t}_{n} ) = {T}_{0} + {\sum }_{i = 1}^{n - 1} Δ T ( {r}_{n i} , {t}_{n} - {t}_{i} )$$

in which T₀ is the initial temperature of the powder,
emitting, at the moment tₙ, a laser beam towards the nth point so as to consolidate an nth zone of the layer of powder comprising the nth point, with the adjusted power.

Said adjusted power, denoted Pₙ, can be calculated depending on the estimate of the temperature before consolidation Tp(tₙ) as follows:

$${P}_{n} = \frac{1}{2 Δ t} ( T s - Tp ( {t}_{n} ) ) ( {R}^{2} + 8 a {t}_{0} ) ɛ \sqrt{{π}^{3} {t}_{0}}$$

in which Δt is a time increment, Ts is a predetermined threshold temperature and to is a predetermined moment.

Scanning Speed and Time Increment

The path in the layer of powder, comprising several points illuminated by the laser, can be scanned at a constant or variable scanning speed of the laser beam.

The paths scanned by the laser corresponding to FIGS. 2 to 12 as presented above have been described several times as being paths scanned by the laser at a constant scanning speed of the laser beam.

However, it is entirely possible for the adjustment of the power of the laser beam depending on the temperature variation estimates to be implemented using paths scanned by the laser beam at a variable scanning speed.

In particular, if, on modulating the power, the uniformity of the temperature remains unsatisfactory, the scanning speed can be modulated to improve the uniformity of the temperature.

In the same way, the paths scanned by the laser corresponding to FIGS. 2 to 12 as presented above have been described several times as being paths scanned with a time increment

Δt=(tₙ−tₙ₋₁)

that is constant for the entire path.

However, it is entirely possible for the adjustment of the scanning speed of the laser beam depending on the temperature variation estimates to be implemented using a variable time increment.

The time increment Δt can be chosen to be variable along the path. In particular, the time increment can be chosen to be smaller in situations in which the successive adjusted powers differ relatively greatly, and to be larger in situations in which the successive adjusted powers differ relatively little.

The path can be split up virtually into segments Sn of identical or different length, which therefore correspond to identical or different laser scan durations. Each segment Sn is scanned by the laser spatially from a first end corresponding to the nth point and temporally from the moment t_{n.}

Temperature Objective

The threshold temperature Ts as appears in the formula

$${P}_{n} = \frac{1}{2 Δ t} ( T s - Tp ( {t}_{n} ) ) ( {R}^{2} + 8 a {t}_{0} ) ɛ \sqrt{{π}^{3} {t}_{0}}$$

corresponds exactly to the temperature of the powder that is achieved at the nth point over which the centre of the laser spot passes at the moment tₙ.

The threshold temperature Ts can therefore be chosen depending on a temperature of the powder that is desired at a point over which the centre of the laser spot passes and at the time of the laser pass.

However, the threshold temperature Ts can be chosen depending on other criteria.

The temperature variation formulas described above make it possible to determine the effect of one or more supplies of energy to the layer of powder at any point and at any moment depending on said supplies.

Since the change in temperatures can be predicted, the threshold temperature Ts can notably be chosen depending on temperature objectives from among the following conditions:
a maximum temperature of the powder that is achieved over time at a point over which the centre of the laser spot passes,
a maximum temperature of the powder that is achieved over time at a point of the layer of powder,
an upper temperature that is not to be exceeded over time at any point of the layer of powder,
a lower temperature that is not to be dropped below at any point of the powder, or
a combination of these conditions that is optionally variable during the manufacturing process.

The determination of the adjusted powers requires the determination of the estimates of the temperature variations of the layer of powder at the different points included on the path.

The determination of the temperature variation estimates can be carried out before the start of the process, or once the manufacturing process has begun.

In the case in which the estimate of the temperature variation of the layer of powder at the nth point that is caused by the emission of the laser beam so as to consolidate a zone of the layer of powder is carried out once the manufacturing process has started, it is necessary to have a calculator or a simulator that processes the different points of the path sufficiently rapidly.

In particular, the speed at which the different points are processed by the simulator needs to be greater than or at least equal to the speed at which the laser beam illuminates or scans these same points.

This makes it possible to take into account any contingency that arises during production without it being necessary to reinitialize the production and the temperature simulation.

Temporal Neighbourhood—Spatial Neighbourhood

The determination of the adjusted powers takes more time the greater the precision of the estimate, i.e. the higher the number of points taken into account.

In order to limit the calculation time without impairing the quality of the estimate, it is possible to define a spatial neighbourhood Vl and a temporal neighbourhood Vt, thereby limiting the number of points already illuminated to be taken into account in the calculations.

The temporal neighbourhood Vt represents the duration of the thermal effects of the scanning of a path segment. Beyond this duration, the effect on the temperature of the powder of the energy diffused into the environment of the scanned segment and supplied during the scanning thereof can be considered to be negligible.

The spatial neighbourhood VI represents the maximum distance of the thermal effects of the scanning of a path segment. Beyond this distance, the effect on the temperature of the powder of the energy diffused into the environment of the scanned segment and supplied during the scanning thereof can be considered to be negligible.

The negligible nature makes it necessary to define a temperature threshold difference D₅. The thermal effects of the scan corresponding to temperature variations below this difference are considered to be negligible.

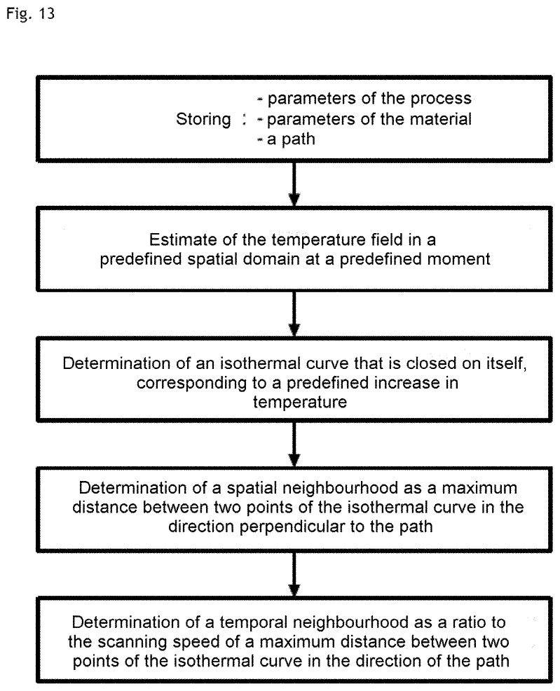

The temporal neighbourhood Vt and the spatial neighbourhood VI can be determined using the following method, illustrated in FIG. 13:

In a first step, the following information is stored in the simulator:
the parameters of the laser scanning process (power of the laser beam and radius of the laser beam, scanning speed of the laser),
the parameters of the material (thermal conductivity, thermal capacity, density, melting point and initial temperature of the powder T₀),
the coordinates of a path of the straight-line portion type.

In a second step, the simulator provides an estimate of the temperature of the powder in a predefined spatial domain which comprises the path defined in the previous step.

The estimate of the temperature provided by the simulator corresponds to the temperature of the powder at a predefined moment located temporally at the end of the scanning of the entire path by the laser after a powder thermalization time.

This estimate can be calculated from elements that have already been defined in advance such as the virtual splitting up of the path into segments and the sum of temperature variations at different points of the spatial domain that are caused by the scanning of each segment by the laser.

At the end of the second step, a map of the temperatures of the powder in the predefined spatial domain at the predefined moment is obtained.

In a third step, an isothermal curve corresponding to the sum

T₀+Dₛ

of the initial temperature of the powder T₀ and the temperature threshold difference D₅ is determined within the temperature map obtained in the second step. This isothermal curve corresponds to an increase in temperature of the temperature threshold difference D₅.

In a fourth step, the spatial neighbourhood is determined as the maximum distance in the direction perpendicular to the path of the straight-line portion type between two points of the isothermal curve determined in the previous step.

In a fifth step, the temporal neighbourhood is determined as the ratio to the scanning speed of the laser of the maximum distance in the direction of the path of the straight-line portion type between two points of the isothermal curve determined in the third step.

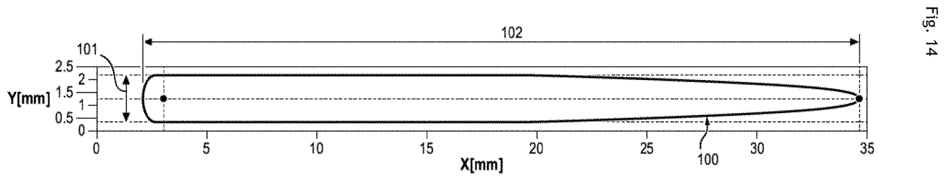

FIG. 14 shows the distances used for determining the spatial neighbourhood and the temporal neighbourhood.

The X axis shown in FIG. 14 represents the direction of the straight-line portion of the path defined in the first step of the above method. The path is scanned in the direction of the increasing values of X. The Y axis represents the direction perpendicular to the path of the straight-line portion type.

The closed curve 100 represents the isothermal curve defined during the third step of the above method.

The spatial neighbourhood corresponds to the length of the segment 101. The maximum distance between two points of the isothermal curve determined in the third step in the direction of the path of the straight-line portion type corresponds to the length of the segment 102.

The ratio of the length of the segment 102 to the scanning speed makes it possible to define the temporal neighbourhood.

Once the spatial neighbourhood VI and the temporal neighbourhood Vt have been determined, these data can be used to limit the calculation time for predetermining the temperature variations making it possible to calculate the adjusted powers in the selective additive manufacturing process.

More specifically, the estimate of a temperature of the powder before consolidation Tₚ at a moment tₙ at an nth point of the layer can be carried out by taking into consideration the temperature variations of the powder that are caused by the emission of a laser beam so as to illuminate n−1 points of the layer of powder, each ith point, where

i=1, 2, . . . (n−1)

being illuminated by the laser beam at the moment tᵢ, and being located at a distance rₙᵢ from the nth point of the layer of powder, such that, for each

i=1, 2, . . . (n−1)

the following inequalities are respected: rₙᵢ≤Vl and |tₙ-tᵢ|≤Vt.

The selective additive manufacturing apparatus 121 shown in FIG. 1 and presented above comprises the control unit 129, which can be configured to control the laser-type source 1212 such that the source emits a laser beam onto a first point of the layer of additive manufacturing powder so as to consolidate a first zone of the layer of powder comprising the first point.

The selective additive manufacturing apparatus 121 may comprise a memory M for storing an estimated temperature variation of the layer of powder at a second point of the layer of powder that is caused by the emission of the laser beam so as to consolidate the first zone of the layer of powder, the estimated temperature variation depending on the distance between the first point and the second point and on a predetermined time interval.

The control unit 129 may be configured to:
adjust a power of the laser beam depending on the estimated temperature variation stored in the memory,
control the laser-type source such that the source emits the laser beam with the adjusted power so as to consolidate a second zone of the layer of powder comprising the second point, the emission of the laser beam onto the first point and the emission of the laser beam onto the second point being temporally separated by the predetermined time interval.

The selective additive manufacturing apparatus 121 may also comprise a calculator or a simulator C, shown in FIG. 1, for determining estimates of temperature variations once the manufacturing process has begun.

The calculator or simulator C is designed to process the different points on the path sufficiently rapidly, in particular the time during which the different points are processed by the calculator or simulator needs to be less than or at least equal to the time taken by the laser beam to illuminate or scan these same points at the predefined speed.

Such a calculator or simulator C can collaborate with the memory M in order to store estimates of temperature variations once they have been produced.

1.-11. (canceled)

12. A process for a selective additive manufacture of a three-dimensional object, the process comprising the steps of:
applying a layer of an additive manufacturing powder on a support or on a previously consolidated layer;
emitting a laser beam onto a first point of the layer so as to consolidate a first zone of the layer comprising the first point;
adjusting a power of the laser beam to a first adjusted power according to an estimated temperature variation ΔT of the layer at a second point of the layer, the second point being different from the first point, the estimated temperature variation ΔT being caused by an emission of the laser beam so as to consolidate the first zone, the estimated temperature variation ΔT depending on a distance between the first point and the second point and on a predetermined time interval; and
emitting a laser beam onto the second point with the first adjusted power so as to consolidate a second zone of the layer, the second zone comprising the second point, the emission of the laser beam onto the first point and the emission of the laser beam onto the second point being temporally separated by the predetermined time interval.

13. The process according to claim 12, wherein the estimated temperature variation ΔT is estimated in advance, depending on the distance r₂₁ between the first point and the second point and on the predetermined time interval (t₂-t₁), by calculating:
$$Δ T ( {r}_{21} , {t}_{2} - {t}_{1} ) = \frac{2 {Q}_{1}}{ɛ \sqrt{{π}^{3} ( {t}_{0} + ( {t}_{2} - {t}_{1} ) )}} \frac{1}{{R}^{2} + 8 a ( {t}_{0} + ( {t}_{2} - {t}_{1} ) )} exp ( \frac{- 2 {( {r}_{21} )}^{2}}{{R}^{2} + 8 a ( {t}_{0} + ( {t}_{2} - {t}_{1} ) )} )$$
Q₁ being an energy received by the layer during the emission of the laser beam so as to consolidate the first zone of the layer, ε being a thermal effusivity of the layer, R being a radius of the laser beam, α being a thermal diffusivity of the layer, and t₀ being a predetermined moment.

14. The process according to claim 12 further comprising the steps of:
adjusting a power of the laser beam to a second adjusted power depending on an estimate of a temperature of the powder before consolidation Tₚ(tₙ) at a moment to at an n-th point of the layer, n being an integer greater than or equal to two, the estimate depending on temperature variations of the powder, the temperature variations being caused by emissions of a laser beam, the emissions of the laser beam being sent so as to consolidate n−1 zones of the layer, the n-th point being located at a distance from an i-th point of the layer, where i=1,2, . . . (n−1), each i-th point being located within an i-th zone of the layer, each i-th point being illuminated by the laser beam at a moment tᵢ, so that
$$Tp ( {t}_{n} ) = {T}_{0} + {\sum }_{i = 1}^{n - 1} Δ T ( {r}_{n i} , {t}_{n} - {t}_{i} )$$
in which T₀ is an initial temperature of the layer; and
emitting, at the moment tₙ, the laser beam with the second adjusted power toward the n-th point so as to consolidate an n-th zone of the layer comprising the n-th point.

15. The process according to claim 14, wherein, in addition, each i-th point is located at a distance rₙᵢ from the n-th point of the layer of powder, the distance rₙᵢ verifies rₙᵢ≤Vl, in which Vl is a predetermined spatial neighborhood, and each moment tᵢ verifies |tₙ-tᵢ|≤Vt, in which Vt is a predetermined temporal neighborhood, where i=1,2, . . . (n−1), and n is an integer greater than or equal to two.

16. The process according to claim 12 further comprising the step of:
calculating the second adjusted power Pₙ according to an estimate of a temperature before consolidation Tp(tₙ) as follows
$${P}_{n} = \frac{1}{2 Δ t} ( T s - Tp ( {t}_{n} ) ) ( {R}^{2} + 8 a {t}_{0} ) ɛ \sqrt{{π}^{3} {t}_{0}}$$
in which Δt is a predetermined time increment and Ts is a predetermined threshold temperature.

17. The process according to claim 12, wherein a threshold temperature Ts is predetermined according to at least one temperature objective chosen from the following conditions:
a temperature of the layer to be reached at a point over which a center of a laser spot of the laser beam passes and at the instant when the center of the laser spot passes over the point,
a maximum temperature of the layer that is reached over time at a point over which a center of a laser spot of the laser beam passes,
a maximum temperature of the layer that is reached over time at a point of the layer,
an upper temperature that is not to be exceeded over time at any point of the layer,
a lower temperature that is not to be dropped below at any point of the layer, and
a combination of these conditions.

18. The process according to claim 12, wherein the laser beam scans along a discontinuous path comprising a first group of mutually parallel straight-line portions.

19. The process according to claim 12, wherein the laser beam scans along a continuous path comprising a first group of mutually parallel straight-line portions and a second group of straight-line portions, each straight-line portion of the second group joining a first end of a first straight-line portion of the first group and a second end of a second straight-line portion of the first group, the second straight-line portion being adjacent to the first straight-line portion.

20. The process according to claim 12, wherein the estimated temperature variation of the layer at the second point of the layer is obtained once the manufacturing process has started.

21. An apparatus for a selective additive manufacture of a three-dimensional object, the apparatus comprising:
a laser-type source;
a control unit configured to control the laser-type source so that the laser-type source emits a laser beam onto a first point of the layer of an additive manufacturing powder, so as to consolidate a first zone of the layer comprising the first point; and
a memory for storing an estimated temperature variation of the layer of powder at a second point of the layer, the estimated temperature variation being caused by an emission of the laser beam so as to consolidate the first zone of the layer, the estimated temperature variation depending on a distance between the first point and the second point and on a predetermined time interval,
wherein the control unit is configured to:
adjust a power of the laser beam to a first adjusted power depending on the estimated temperature variation stored in the memory, and
control the laser-type source so that the laser-type source emits a laser beam onto the second point with the first adjusted power so as to consolidate a second zone of the layer, the second zone comprising the second point, the emission of the laser beam onto the first point and the emission of the laser beam onto the second point being temporally separated by the predetermined time interval.

22. The apparatus according to claim 21 further comprising:
a calculator or a simulator configured to determine estimates of temperature variations of the layer at an n-th point, the temperature variations being caused by emissions of the laser beam so as to consolidate one or more zones of the layer once the manufacturing process has begun.
